(19) United States
(12) Patent Application Publication
(10) Pub. No.: US 2012/0049314 A1
(43) Pub. Date: Mar. 1, 2012

(54) Thermoelectric module and method for fabricating the same

(75) Inventors: Yong Suk Kim, Yongin-si (KR); Sung Ho Lee, Seongnam-si (KR); Young Soo Oh, Seongnam-si (KR); Tae Kon Koo, Seoul (KR)

(73) Assignee: SAMSUNG ELECTRO-MECHANICS CO., LTD., Suwon (KR)

(21) Appl. No.: 13/137,503

(22) Filed: Aug. 22, 2011

(30) Foreign Application Priority Data
Aug. 27, 2010 (KR) 10-2010-0083373

(51) Int. Cl. H01L 31/058; H01L 31/18

(52) U.S. Cl. 257/467; 438/54; 257/E31.054

(57) ABSTRACT

The present invention relates to a thermoelectric module. The thermoelectric module includes a first substrate and a second substrate opposed to each other and arranged to be separated from each other, a first electrode and a second electrode arranged in the inside surfaces of the first and the second substrates, respectively, a thermoelectric device inserted between the first and the second electrodes and electrically connected to the first and the second electrodes; and an elastic member filled between the first and the second substrates.

### CROSS-REFERENCE TO RELATED APPLICATIONS

This application claims the benefit of Korean Patent Application No. 10-2010-0083373 filed with the Korea Intellectual Property Office on Aug. 27, 2010, the disclosure of which is incorporated herein by reference.

### BACKGROUND OF THE INVENTION

1. Field of the Invention

The present invention relates to a thermoelectric module and a method for fabricating the same; and, more particularly to a thermoelectric module without a pointer between a substrate and a thermoelectric device and a method for fabricating the same.

2. Description of the Related Art

The thermoelectric module can operate as a solid state heat pump and utilize as a cooler or a heater. Since the thermoelectric module has high reliability with a simple structure and without mechanical operational elements, it has advantages of low noise and vibration as well as miniaturization in comparison with a conventional cooler using such as a compressor.

Also, the thermoelectric module is capable of performing rapid and accurate temperature control and cooling/heating conversion with simple operation, thereby applying to a high precise cooler/thermostat, an optical element device, an optical sensor and precise electric products.

Also, since the thermoelectric module realizes cooling and heating at the same time in one module by changing the polarity of direct power, it can be effectively utilized for an air handling unit or the like. It can be utilized for the other product, for example, a compact cooling device, a cosmetic refrigerator, a wine refrigerator, a hot and cold water purifier, a cooling sheet for vehicles, semiconductor equipment and a cooling/thermostat device such as a precision thermostat chamber.

In order to fabricate such thermoelectric module, the size of device, characteristics, junction and packaging and the like become main issues. According to the design of the module and the manufacturing method, the characteristics of the thermoelectric module can be determined along with the characteristics and durability, reliability and the other environments.

In the conventional method, the thermoelectric module is formed by joining the thermoelectric device on a flat substrate, at this time; an incomplete junction is generated by the non-uniformity of the substrate thickness or the accuracy failure of patterns, thereby generating a local junction failure and the increment of contact resistance.

Such module generates efficiency degradation including the performance index of the thermoelectric module and deterioration due to thermal shock and moisture, thereby causing the reliability deterioration or the like.

### SUMMARY OF THE INVENTION

The present invention has been proposed in order to overcome the above-described problems and it is, therefore, an object of the present invention to provide a thermoelectric module and a method for fabricating the same capable of solving problems such as a local junction failure due to incomplete junction and the increment of contact resistance to be generated by the non-uniformity of substrate thickness or the inaccuracy of patterns; and, more particularly problems such as the local junction failure and the increment of contact resistance by filing an elastic member between a first substrate and a second substrate to realize complete junction.

In accordance with one aspect of the present invention to achieve the object, there is provided a thermoelectric module including a first substrate and a second substrate opposed to each other and arranged to be separated from each other, a first electrode and a second electrode arranged in the inside surfaces of the first and the second substrates, respectively, a thermoelectric device inserted between the first and the second electrodes and electrically connected to the first and the second electrodes and an elastic member filled between the first and the second substrates.

Any one surface of one side surface and the other surface of the elastic member surface is physically or chemically connected to any one side among the first substrate and the second substrate and the remaining one surface is connected to the remaining substrate.

Herein, the remaining one surface of the elastic member is provided with embossing or unevenness.

Herein, thermal grease can be further included between the remaining one surface of the elastic member and the side of the remaining substrate.

Herein, the elastic member includes a first elastic body and a second elastic body, one side surface of the first elastic body is physically or chemically connected to the side of the first substrate and the other side surface of the second elastic body is physically or chemically connected to the side of the second substrate, and the other side surface of the first elastic body is contact to the one side surface of the second elastic body.

Herein, embossing or unevenness is formed on the other side surface of the first elastic member or the one side surface of the second elastic body.

Herein, thermal grease can be further included between the other side surface of the first elastic body and the one side surface of the second elastic body.

Herein, the elastic member can include any one among ABS (Acrylonitrile Butadiene Styrene), PMMA (PolyMethoy MethAcrylate) and Tefron.

Herein, the elastic member can further include ceramic powder.

Herein, the thermal grease can be further inserted in at least one place located between the first substrate and the first electrode, the second substrate and the second electrode, the thermoelectric device and the first electrode and the thermoelectric device and the second electrode.

Herein, the thermoelectric device is connected to the first and second electrodes each other through the solder.

In accordance with another aspect of the present invention to achieve the object, there is provided a method for fabricating a thermoelectric module including the steps of: forming a first substrate where a first electrode, a first solder layer and a thermoelectric device are arranged by being stacked; forming a second substrate where a second electrode and a second solder layer corresponding to the thermoelectric device by being stacked; arranging the second substrate on the first substrate in such a way that the elastic member is filled between the first substrate and the second substrate; and forming the thermoelectric module by connecting the first and the second electrodes to the thermoelectric device each other by the first and the second solder layers through a reflow process.

Herein, the elastic member has the same height of the thermoelectric module in thickness or higher.

Herein, the step of filling the elastic member between the first substrate and the second electrode is a step of forming the elastic member on the first substrate on which the first electrode, the first solder layer and the thermoelectric device are arranged, wherein the thickness of the elastic member is the same height of the thermoelectric device or higher.

Herein, after the step of forming the elastic member, a step of forming embossing or unevenness can be further included by performing embossing process or unevenness process to the exposed surface of the elastic member.

Herein, the step of filling the elastic member between the first substrate and the second electrode includes the steps of: forming a first elastic body on the first substrate where the first electrode, the first solder layer and the thermoelectric device are arranged; and forming a second elastic body on the second substrate where the second electrode is arranged.

Herein, before the step arranging the second substrate on the first substrate, a step of forming embossing or unevenness can be further included by performing embossing process or unevenness process to the exposed surface of the first elastic body formed on the first substrate or the exposed surface of the second elastic body formed on the second substrate.

Herein, the thermal grease can be further formed in at least one place located between the first substrate and the first electrode, the second substrate and the second electrode, the thermoelectric device and the first electrode and the thermoelectric device and the second electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a thermoelectric module in accordance with one embodiment of the present invention;

FIGS. 2a to 2b are enlarged views expanding the region A of FIG. 1;

FIGS. 3 to 6 are cross-sectional views showing a method for fabricating a thermoelectric module in accordance with another embodiment of the present invention; and

FIGS. 7 to 9 are cross-sectional views showing a method for fabricating a thermoelectric module in accordance with still another embodiment of the present invention.

### DETAILED DESCRIPTION OF THE PREFERABLE EMBODIMENTS

Embodiments of the present invention will be described in detail with reference to the accompanying drawings. The embodiments described hereinafter will be provided as examples so that the scope of the invention is fully conveyed to those skilled in the art.

Therefore, this invention may be embodied in many different forms and should not be construed as limited to the exemplary embodiments set forth herein. And, in the drawings, the size and relative sizes of layers and regions may be exaggerated for clarity. Like reference numerals in the drawings denote like elements.

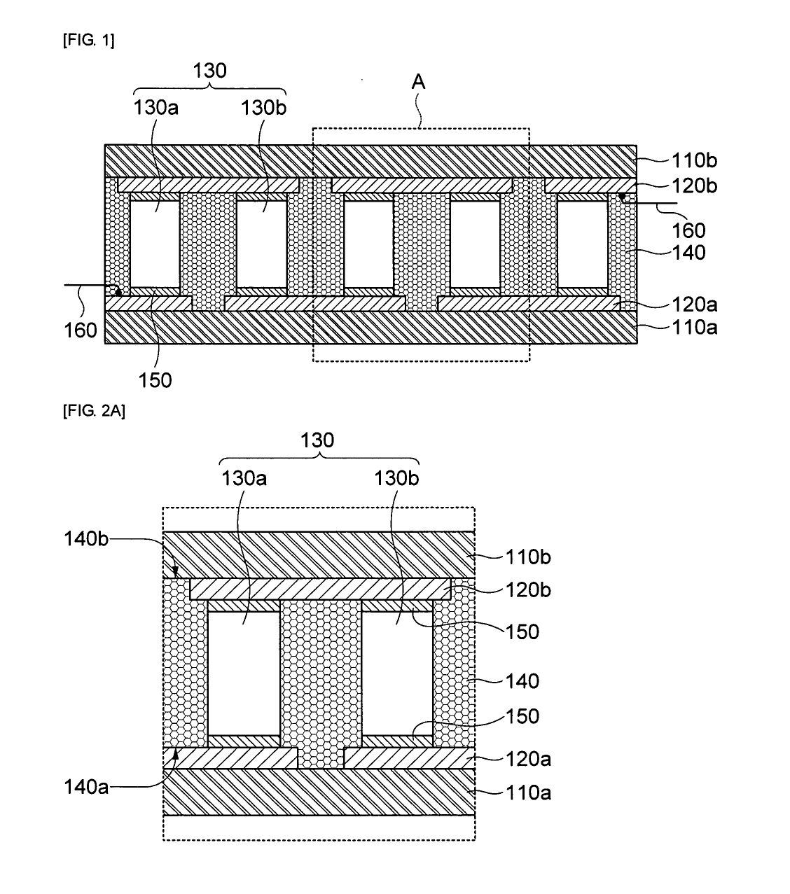

FIG. 1 is a cross-sectional view showing a thermoelectric module in accordance with one embodiment of the present invention.

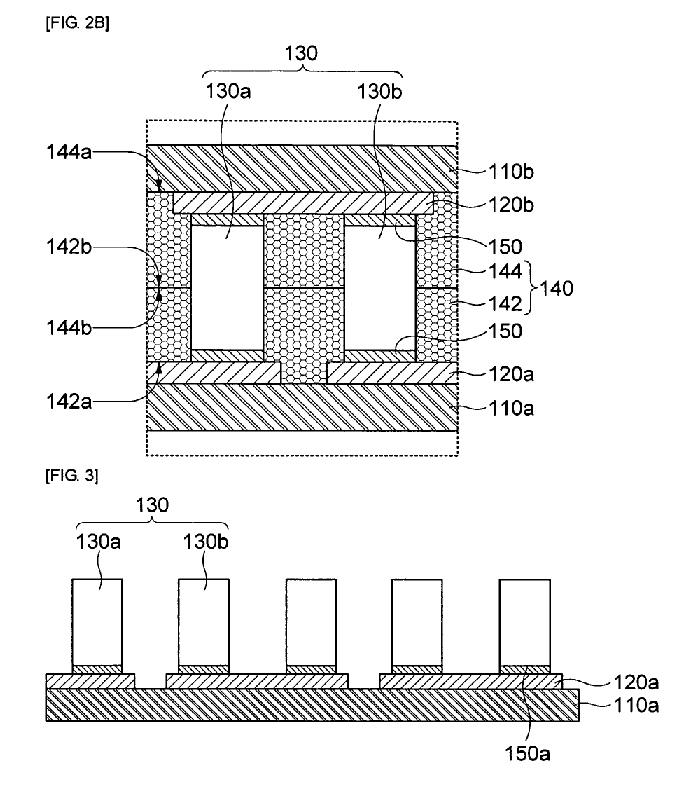

FIGS. 2a to 2b are enlarged views expanding the region A of FIG. 1.

Referring to FIGS. 1 to 2b, a thermoelectric module 100 in accordance with the present invention includes a first substrate 110a and a second substrate 110b separated with opposing to each other, a first electrode 120a and a second electrode 120b inserted inside surfaces of the first and second substrates 110a and 110b and a thermoelectric device 130 inserted between the fist and second substrate 110a and 110b.

Also, the thermoelectric module 100 may include an elastic member 140 filed between the first and second substrates 110a and 110b.

The first and second substrates 110a and 110b may play a role of supporting the thermoelectric device 130 and the first and second electrodes 120a and 120b. Further, if the thermoelectric device 130 is formed by a plurality of pieces, the first and second substrates 110a and 110b may play a role of connecting the plurality of thermoelectric devices 130.

And also, the first substrate 110a and the second substrate 110b can play the role of absorbing heat from outside or discharging the heat to the outside through the heat exchange of the thermoelectric device 130 by being connected to an external apparatus. That is, the first substrate 110a and the second substrate 110b can play the role of performing the heat exchange between the external apparatus and the thermoelectric device 130. Therefore, the efficiency of the thermoelectric module 100 can be affected by the thermal conductivity of the first and second substrates 110a and 110b.

In order to this, the first and second substrates 110a and 110b can be made of ceramic having high thermal conductivity.

Also, the first and second substrates 110a and 110b can be made of metal having excellent thermal conductivity. For example, the first and second substrates 110a and 110b can be made of aluminum and copper or the like. In this result, the thermoelectric efficiency can be improved by allowing the first and second substrates 110a and 110b to have excellent thermal conductivity.

At this time, between the inside surfaces of the first substrate 110a and the second substrate 110b, specifically between the first substrate 110a and the first electrode 120a and between the second substrate 110b and the second electrode 120b, the electric insulating property of the first and second substrates 110a and 110b can be endowed by arranging the insulating layer (not shown) to insulate between the first and second substrates 110a and 110b and the first and second electrodes 120a and 120b made of metal. At this time, the insulating layer can be made of material having durability capable of withstanding the process to form the thermoelectric module 100. For example, the insulating layer can be made of any one among SiO₂, Al₂O₃, TiO₂, ZnO, NiO and Y₂O₃.

Herein, the insulating layer can be formed in a thickness ranging from 0.2 μm to 10 μm. If the thickness of the insulating layer is below 0.2 μm, it is difficult to secure the insulation property. Whereas, if the thickness of the insulating layer is above 10 μm, it can deteriorate the thermal conductivity between the first substrate 110a or the second substrate 110b and the thermoelectric device 130.

Further, the insulating layer can play a role of securing the insulation property of the first substrate 110a and the second substrate 110b as well as it can further perform a role of filling air gaps formed in the first substrate 110a and the second substrate 110b. Hereby, it can prevent the heat transmission from being deteriorated by the air gaps between the first substrate 110a and the first electrode 120a and between the second substrate 110b and the second electrode 120b.

On the other hand, the thermoelectric device 130 can include a P-type semiconductor 130a and an N-type semiconductor 130b. At this time, the P-type semiconductor 130a and the N-type semiconductor 130b can be alternatively arranged on the same plane.

At this time, the first and second electrodes 120a and 120b can be arranged to face each other with placing the thermoelectric device 130 therebetween. At this time, a pair of P-type semiconductor 130a and N-type semiconductor 130b are electrically connected by the first electrode 120a placed at the bottom surface therebelow and another pair of neighboring P-type semiconductor 130a and the N-type semiconductor 130b can be electrically connected by the second electrode 120b located on the top surface thereof.

The first electrode 120a and the second electrode 120b and the thermoelectric device 130 can be connected to each other by a solder 150. Herein, the solder 150 can include Sn such as PbSn or CuAgSn.

In addition, the first and second electrodes 120a and 120b can supply power to an external power unit or receive power by being connected to the external power unit through a wire 160. That is, if the thermoelectric module 100 plays a role of a generating apparatus, the power can be supplied to the external power unit, and if it plays a role of a cooling apparatus, the power can be received from the external power unit.

Also, not shown in the drawings, thermal grease can be inserted between interfaces between each element. For example, the thermal grease can be inserted in at least one place located between the first substrate 110a and the first electrode 120a, between the second substrate 120 and the second electrode 120b, the thermoelectric device 130 and the first electrode 120a and the thermoelectric device 130 and the second electrode 120b. Herein, the thermal grease plays the role of filling the air gaps formed in each interface, thereby playing a role to prevent the thermal conductivity from being deteriorated by the air gaps.

The elastic member 140 is filled between the first substrate 110a and the second substrate 110b, specifically between a portion of the first substrate 110a and a portion of the first electrode 120a at the side of the first substrate 110a and a portion of the second substrate 110b and a portion of the second electrode 120b.

The elastic member 140 prevents local junction failures from being generated since non-contact points are not generated between the thermoelectric device 130 and the first substrate 110a or the second substrate 110b, and prevents problems such as contact resistance increments due to the local junction failures from being generated. Also, the elastic member 140 improves the junction strength between the first substrate 110a and the second substrate 110b, in this results, it improves the durability of the thermoelectric module 100. This is achieved since the elastic member 140 is capable of absorbing pressure of contact imbalance generated during the connection between the first substrate 110a and the second substrate 110b by using its elastic force.

At this time, as shown in FIG. 2a, any one surface among one side surface 140a as the surface at the side of the first substrate 110a and the other side surface 140b as the surface at the side of the second substrate 110b is physically or chemically connected to any one substrate side among the first substrate 110a and the second substrate 110b, and the remaining one surface can be in contact with the side of the remaining substrate.

For example, among the surfaces of the elastic member 140, the one side surface 140a as a surface at the side of the first substrate 110a is physically or chemically connected to the side of the first substrate 110a, more specifically a predetermined region of the first substrate 110a and a predetermined region of the first electrode 120a, and the other surface of the elastic member 140 may be contact with the side of the surface 140b of the first substrate 110a, more specifically a predetermined region of the second substrate 110b and a predetermined region of the second electrode 120b. Inversely, the elastic member 140 can be physically and chemically connected to the side of the second substrate 110b.

At this time, not shown in the drawings, any one surface of the elastic member 140 contact with the side of the first substrate 110a or the second substrate 110b may include embossing or unevenness. And also, on any one surface of the elastic member 140 contact with the side of the first substrate 110a or the second substrate 110b, thermal grease may be further inserted. At this time, the embossing or the unevenness provided on the any one surface of the elastic member 140 contact with the side of the first substrate 110a or the second substrate 110b increases the adhesive force between the elastic member 140 and the substrates and the thermal grease may be inserted to increase the adhesive force to the substrates as well as to increase the thermal conductivity.

The elastic member 140 may be made of by including any one among ABS (Acrylonitrile Butadiene Styrene), PMMA (PolyMethyl MethaAcrylate) and Teflon, it can further include ceramic powder to improve the insulation property or the heat resistance property.

On the other hands, the elastic member 140 filled between the first electrode 120a and the second electrode 120b is filled with the same thickness of the separation distance between the first electrode 10a and the second electrode 120b at least or it is preferable that the elastic member 140 is filled thicker than the separation distance, and the elastic member 140 filled between the first substrate 110a and the second substrate 110b is filled with the thickness equal to the separation distance between the first substrate 110a and the second substrate 110b or the thicker.

This is to sufficiently secure the elastic force when the elastic member 140 is connected to the first substrate 110a and the second substrate 110b.

Also, the elastic member 140 may include the first elastic body 142 and the second elastic body 144 as shown in FIG. 2b.

The one side surface 142a of the first elastic body 142 is physically or chemically connected to the side of the first substrate 110a and the other side surface 144b of the second elastic body 144 may be physically or chemically connected to the side of the second substrate 110b. And, the other side 142b of the first elastic body 142 may be in contact with the one side surface 144a of the second elastic body 144.

At this time, the first elastic body 142 and the second elastic body 144 may be formed material matching with each property since they are physically or chemically connected to the sides of the first substrate 110a and the second substrate 110b. For example, if the side of the second substrate 110b is a high temperature part to absorb heat and the side of the first substrate 110a is a low temperature part to discharge heat, each of the first elastic body 142 and the second elastic body 144 may be formed of material appropriate to the high temperature and the low temperature, respectively. Needless to say, the first elastic body 142 and the second elastic body 144 may be formed with the same material, may be made of by including any one among ABS (Acrylonitrile Butadiene Styrene), PMMA (PolyMethyl MethAcrylate) and Teflon, and may further include ceramic powder to improve the insulation property or the heat resistance property.

The thermal grease may be inserted between the other side surface 142b of the first elastic body 142 and the one side surface 144a of the second elastic body 144 and the embossing or the unevenness can be included on any one surface among the other side surface 142b of the first elastic body 142 and the one side surface 144a of the second elastic body 144. At this time, the embossing or the unevenness increases the adhesive force between the first elastic body 142 and the second elastic body 144 and the thermal grease increases the adhesive force between the first elastic body 142 and the second elastic body 144 as well as increases the thermal conductivity.

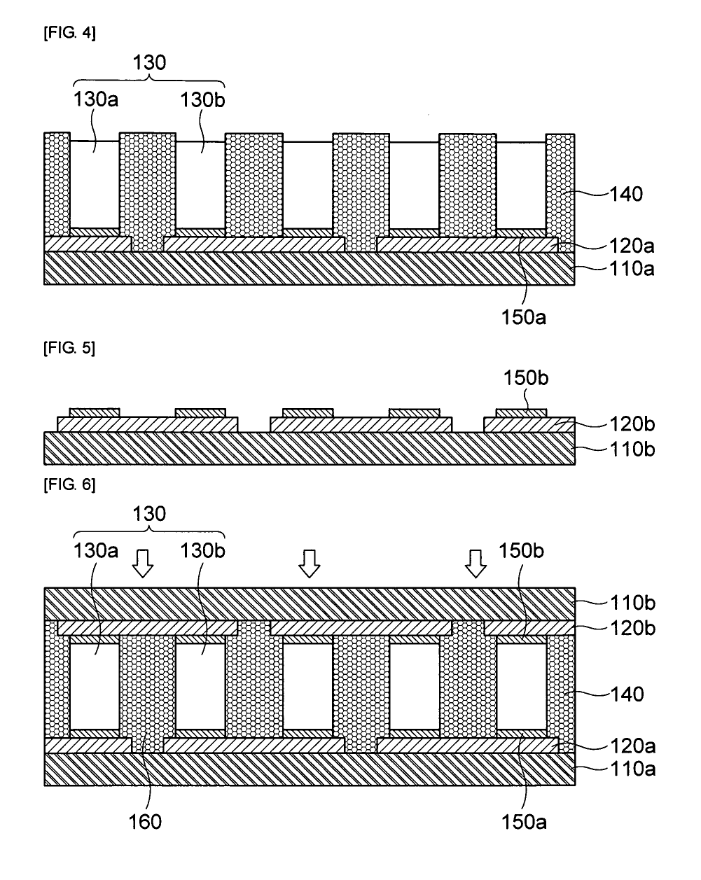

FIGS. 3 to 6 are cross-sectional views showing a method for fabricating a thermoelectric module in accordance with another embodiment of the present invention.

Referring to FIGS. 3 to 6, the method for fabricating the thermoelectric module in accordance with another embodiment of the present invention will be described in detail.

Referring to FIG. 3, in order to manufacture the thermoelectric module, a first substrate 110a is prepared at first.

The first substrate 110a may be a ceramic substrate made of ceramic.

And also, the first substrate 110a may be made of metal material having excellent thermal conductivity, if the first substrate 110a is made of the metal material, an insulating layer (not shown) can be formed on the inside surface of the first substrate 110a.

The insulating layer can be made of any one among SiO₂, Al₂O₃, TiO₂, ZnO, NiO and Y₂O₃. Herein, one example of methods for forming the insulating layer is a printing method, an ALD (Atom Layer Deposition) method, a sputtering method, an E-beam method and a CVD (Chemical Vapor Deposition) method or the like, and the insulating layer can be formed in a thickness ranging from 0.2 μm to 10 μm considering on the effect to the secured insulation and thermal conductivity.

The first electrode 120a is formed on the inside surface of the first substrate 110a. Herein, after a conductive layer is formed by depositing conductive material, the first electrode 120a can be formed by patterning the conductive layer. However, it is not limited to this in the embodiments of the present invention; for example, the first electrode 120a can be formed through a plating process and a printing process or the like.

And then, a first solder layer 150a is formed on the first electrode 120a. The first solder layer 150a can be formed by printing conductive paste including Sn such as PbSn or CuAgSn or the like.

And then, the thermoelectric device 130 is arranged on the first solder layer 150a. Herein, the thermoelectric device 130 can include a P-type semiconductor 130a and an N-type semiconductor 130b, at this time the P-type semiconductor 130a and the second surface improvement layer 130b can be exchanged alternately.

Referring to FIG. 4, the elastic member 140 is formed on the first substrate 110a where the first electrode 120a, the first solder layer 150a and the thermoelectric device 130 are arranged by being sequentially stacked.

Herein, when the thermoelectric module 100 is formed by joining the first substrate 110a and the second substrate 110b, the elastic member 140 is formed to be filled between the first substrate 110a and the second substrate 110b. At this time, the elastic member 140 is formed to fill the first substrate 110a, more specifically by being formed on a predetermined region of the first substrate 110a exposed on which the first electrode is not arranged and a predetermined region of the first electrode 120a exposed by nor arranging the first solder layer 150a and the thermoelectric device 130, as shown in FIG. 4.

At this time, the elastic member 140 is formed at the same thickness of the height of the thermoelectric device 130, preferably thicker than the height of the thermoelectric device 130 to protrude above the thermoelectric device 130. The reason is that the non-contact points between the first substrate 110a and the second substrate 110b are not generated by generating the elastic force since the elastic member 140 is pressed at a predetermined pressure when the first substrate 110a and the second substrate 110b are joined.

At this time, an embossing treatment or a process for forming unevenness can proceed to the exposed surface of the elastic member 140. And also, the thermal grease can be formed on the exposed surface of the elastic member 140. The embossing or the unevenness formed on the exposed surface of the elastic member 140 increases the adhesive force during the joining between the first substrate 110a and the second substrate 110b and the thermal grease plays a role of increasing the thermal conductivity.

Referring to FIG. 5, the second substrate 110b is prepared, separately from a process for forming the first electrode 120a, the first solder layer 150a and the thermoelectric device 130 on the first substrate 110a, and a process for forming the second electrode 120b and the second solder layer 150b on the inside surfaces of the second substrate 110b is proceeded.

At this time, the second substrate 110b may be the ceramic substrate made of the ceramic similar to the first substrate 110a; may be the metal material having excellent thermal conductivity; and, when the second substrate 110b is made of metal material, an insulation layer (not shown) can be formed on the inside surface of the second substrate 110b.

The second electrode 120b and the second solder layer 150b are sequentially formed on the inside surface of the second substrate 110b. Herein, the insulating layer, the second electrode 120b and the solder layer 150b can be equal to the materials of the insulating layer, the first electrode 120a and the first solder layer 150a described with reference to FIG. 4, and can be formed through the same forming method.

Referring to FIG. 6, after the second substrate 110b is arranged on the first substrate 110a to make the second electrode 120b be contact with the thermoelectric device 130 each other, while a predetermined pressure is applied to the second substrate 110b or the first substrate 110a, the thermoelectric module 100 can be fabricated by joining the first and second electrodes 120a and 120b to the thermoelectric device 130 each other through a reflow process.

At this time, the predetermined pressure applied to the first substrate 110a plays a role of joining the first substrate 110a to the second substrate 110b without non-contact points by allowing the elastic member 140 filled between the first substrate 110a and the second substrate 110b to have the elastic force.

In addition, although not shown in the drawings, thermal grease can be inserted between interfaces between each element. For example, the thermal grease can be inserted in at least one place located between the first substrate 110a and the first electrode 120a, between the second substrate 120 and the second electrode 120b, the thermoelectric device 130 and the first electrode 120a and the thermoelectric device 130 and the second electrode 120b.

In addition, although not shown in the drawings, a process to connect a wire 160 to the first electrode 120a and the second electrode 120b may be proceeded so as to connect the wire 160 to the first electrode 120a and the second electrode 120b similar to the thermoelectric module 100 as shown in FIG. 1.

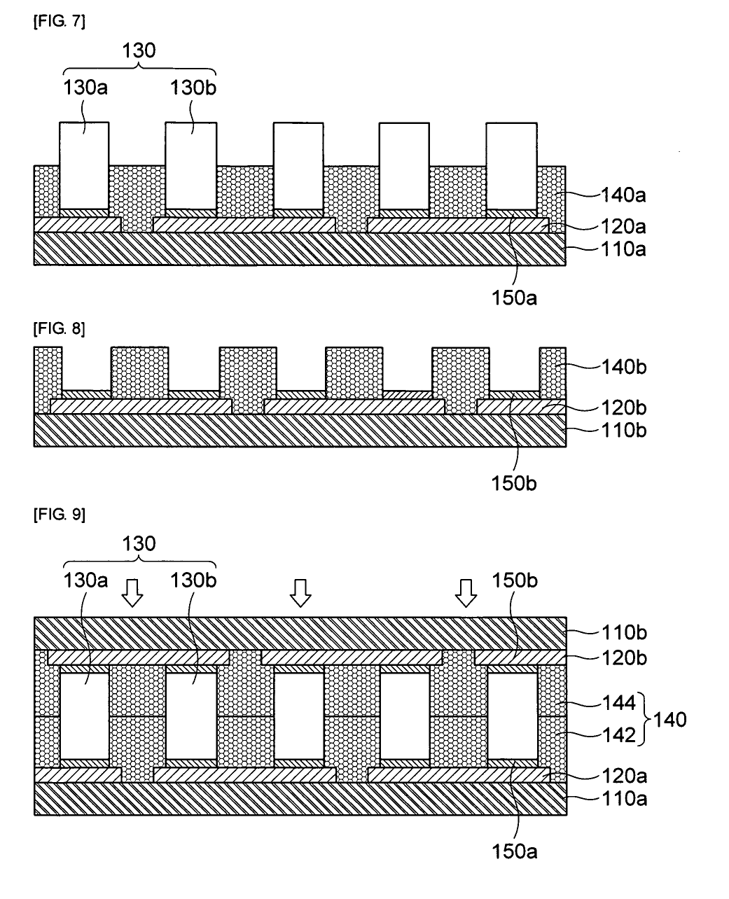

FIGS. 7 to 9 are cross-sectional views showing a method for fabricating a thermoelectric module in accordance with still another embodiment of the present invention.

Referring to FIGS. 7 to 9, the method for fabricating the thermoelectric module in accordance with still another embodiment of the present invention will be described in detail.

Referring to FIG. 7, in order to fabricating the thermoelectric module, the first substrate 110a is supplied at first.

The first electrode 120a, the first solder layer 150a and the thermoelectric device 130 are formed on the inside surface of the first substrate 110a. At this time, the insulation layer can be further formed according to the material of the first substrate 110a.

Herein, the first electrode 120a, the first solder layer 150a and the thermoelectric device 130 may be made of the same materials of the insulation layer, the first electrode 120a, the solder layer 150a and the thermoelectric device 130 described with reference to FIG. 3, and the detail explanation will be omitted since they can be formed through the same fabrication methods.

And then, the first elastic body 140a is formed on the first substrate 110a. At this time, the first elastic body 140a can be formed at an appropriate thickness considering on the thickness of the second elastic body 140b to be explained hereinafter so as to be filled between the first substrate 110a and the second substrate 110b by playing the same role of the elastic member 140 described with reference to FIG. 4 by being joined with the second elastic body 140b to be explained hereinafter. At this time, it is preferable that the first elastic body 140a is formed at a half-thickness of elastic member 140 described with reference to FIG. 4.

Herein, the embossing process or the unevenness process can be applied to the exposed surface of the second elastic body 140b; and also, the thermal grease can be formed.

Referring to FIG. 8, the second substrate 110b is supplied.

And then, the second electrode 120b and the second solder layer 150b are formed inside surfaces of the second substrate 110b.

Herein, the second electrode 120b and the second solder layer 150b can be made of the same materials of the second electrode 120b and the second solder layer 150b described with reference to FIG. 5 and the detail description will be omitted since they can be formed through the same forming method.

And then, the second elastic body 140b is formed on the second substrate 110b. At this time, the second elastic body 140b can be formed at an appropriate thickness considering on the thickness of the first elastic body 140a to be explained hereinafter so as to be filled between the first substrate 110a and the second substrate 110b by playing the same role of the elastic member 140 described with reference to FIG. 4 by being joined with the first elastic body 140a described above. At this time, it is preferable that the second elastic body 140b is formed at the same thickness of the first elastic body 140a when it is formed at a half-thickness of elastic member 140 described with reference to FIG. 4.

Herein, the embossing process or the unevenness process may be applied to the second elastic body 140b at the surface exposed equally to the first elastic body 140a; and also, the thermal grease can be formed.

Referring to FIG. 9, after the second substrate 110b is arranged on the first substrate 110a to make the thermoelectric device be contact with the second electrode 120b, the thermoelectric module can be manufactured by joining the first and second electrodes 120a and 120b each other through a reflow process with applying a predetermined pressure to the first substrate 110a and the second substrate 110b.

At this time, the predetermined pressure applied to the first substrate 110a and the second substrate 110b plays a role of joining the first substrate 110a and the second substrate 110b without non-contact points by having an elastic force with adhering the first elastic body 140a to the second elastic body 140b filled between the first substrate 110a and the second substrate 110b.

In addition, although not shown in the drawings, the thermal grease can further formed on the interfaces between each element, for example, on at least one place among between the first substrate 110a and the first electrode 120a, between the second substrate 110b and the second electrode 120b, between the thermoelectric device 130 and the first electrode 120a and the thermoelectric device 130 and the second electrode 120b.

In addition, although not shown in the drawings, in order to connect the wire 160 to each of the first electrode 120a and the second electrode 120b similar to the thermoelectric module 100 as shown in FIG. 1, a process to connect the wire 160 to the first electrode 120a and the second electrode 120b can be proceeded.

The thermoelectric modules in accordance with embodiments of the present invention have advantages that the conventional problems such as a local contact failure and the increment of contact resistances are not generated by not making the non-contacts be generated between the thermoelectric device and the first substrate or the second substrate.

Also, the thermoelectric modules in accordance with embodiments of the present invention have advantages that the adhesive strength is increased by providing the elastic member between the first substrate and the second substrate to thereby enlarging the durability thereof.

Also, the thermoelectric modules in accordance with embodiments of the present invention have advantages that the large size of the thermoelectric module can be easily manufactured since the flatness is secured by the elastic member.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A thermoelectric module comprising:
a first substrate and a second substrate opposed to each other and arranged to be separated from each other;
a first electrode and a second electrode arranged in the inside surfaces of the first and the second substrates, respectively;
a thermoelectric device inserted between the first and the second electrodes and electrically connected to the first and the second electrodes; and
an elastic member filled between the first and the second substrates.

2. The thermoelectric module of claim 1, wherein any one surface of one side surface and the other surface of the elastic member surface is physically or chemically connected to any one side among the first substrate and the second substrate and the remaining one surface is connected to the remaining substrate.

3. The thermoelectric module of claim 2, wherein the remaining one surface of the elastic member is provided with embossing or unevenness.

4. The thermoelectric module of claim 3, further comprising thermal grease between the remaining one surface of the elastic member and the side of the remaining substrate.

5. The thermoelectric module of claim 1, wherein the elastic member includes a first elastic body and a second elastic body,
one side surface of the first elastic body is physically or chemically connected to the side of the first substrate and the other side surface of the second elastic body is physically or chemically connected to the side of the second substrate, and
the other side surface of the first elastic body is contact to the one side surface of the second elastic body.

6. The thermoelectric module of claim 5, wherein embossing or unevenness is formed on the other side surface of the first elastic member or the one side surface of the second elastic body.

7. The thermoelectric module of claim 6, further comprising thermal grease between the other side surface of the first elastic body and the one side surface of the second elastic body.

8. The thermoelectric module of claim 1, wherein the elastic member includes any one among ABS (Acrylonitrile Butadiene Styrene), PMMA (PolyMethoy MethAcrylate) and Tefron.

9. The thermoelectric module of claim 8, wherein the elastic member further includes ceramic powder.

10. The thermoelectric module of claim 1, further comprising thermal grease in at least one place located between the first substrate and the first electrode, the second substrate and the second electrode, the thermoelectric device and the first electrode and the thermoelectric device and the second electrode.

11. The thermoelectric module of claim 1, wherein the thermoelectric device is connected to the first and second electrodes each other through the solder.

12. A method for fabricating a thermoelectric module comprising:
forming a first substrate where a first electrode, a first solder layer and a thermoelectric device are arranged by being stacked;
forming a second substrate where a second electrode and a second solder layer corresponding to the thermoelectric device by being stacked;
arranging the second substrate on the first substrate in such a way that the elastic member is filled between the first substrate and the second substrate; and
forming the thermoelectric module by connecting the first and the second electrodes to the thermoelectric device each other by the first and the second solder layers through a reflow process.

13. The method of claim 12, wherein the elastic member has the same height of the thermoelectric module in thickness or higher.

14. The method of claim 12, wherein the filling the elastic member between the first substrate and the second electrode is forming the elastic member on the first substrate on which the first electrode, the first solder layer and the thermoelectric device are arranged, wherein the thickness of the elastic member is the same height of the thermoelectric device or higher.

15. The method of claim 14, further comprising, after the forming the elastic member, forming embossing or unevenness by performing embossing process or unevenness process to the exposed surface of the elastic member.

16. The method of claim 12, wherein the filling the elastic member between the first substrate and the second electrode includes:
forming a first elastic body on the first substrate where the first electrode, the first solder layer and the thermoelectric device are arranged; and
forming a second elastic body on the second substrate where the second electrode is arranged.

17. The method of claim 13, further comprising, before the arranging the second substrate on the first substrate, forming embossing or unevenness by performing embossing process or unevenness process to the exposed surface of the first elastic body formed on the first substrate or the exposed surface of the second elastic body formed on the second substrate.

18. The method of claim 12, further comprising thermal grease at least one place located between the first substrate and the first electrode, the second substrate and the second electrode, the thermoelectric device and the first electrode and the thermoelectric device and the second electrode.
